(19) United States
(12) Patent Application Publication
(10) Pub. No.: US 2020/0412341 A1
(43) Pub. Date: Dec. 31, 2020

(54) Method For Filtering A Periodic, Noisy Measurement Signal Having A Fundamental Frequency And Harmonic Oscillation Components

(71) Applicant: AVL LIST GmbH, Graz (AT)

(72) Inventors: Raja Sangili Vadamalu, Darmstadt (DE); Christian Beidl, Eggersdorf (AT); Maximilian Bier, Darmstadt (DE)

(21) Appl. No.: 16/957,118

(22) PCT Filed: Dec. 28, 2018
(86) PCT No.: PCT/EP2018/097067

§ 371 Date: Jun. 23, 2020

(30) Foreign Application Priority Data
Dec. 29, 2017 (AT) A51088/2017

(51) Int. Cl. H03H 17/02; G01L 25/00; G01M 15/02; G01M 15/12

(52) U.S. Cl. CPC H03H 17/0219; G01M 15/12; G01M 15/02; G01L 25/003

(57) ABSTRACT

A filter that is capable of filtering a noisy, periodic measurement signal having oscillations at a variable fundamental frequency and harmonic oscillation components of the fundamental frequency. The measurement signal is subjected to low pass filtering in a low-pass filter of the filter with a cutoff frequency greater than the fundamental frequency. A harmonic oscillation component of the measurement signal as an n-fold of the fundamental frequency is determined in at least one self-adaptive harmonic filter of the filter. The at least one harmonic oscillation component is added to the low-pass-filtered measurement signal, the resultant sum is substracted from the measurement signal, and the resultant difference is used as input into the low pass filter. The measurement signal subjected to low pass filtering in the low-pass filter is output by the filter as a filtered measurement signal.

### TECHNICAL FIELD

The present teaching relates to a method for filtering a periodic, noisy measurement signal having a fundamental frequency and harmonic oscillation components of the fundamental frequency with a filter. The present teaching further relates to the use of such a filter on a test bench.

### BACKGROUND

For an internal combustion engine, the effective torque, i.e. the torque which accelerates the inertia of the internal combustion engine and any components connected to it (drive train, vehicle), is an important variable. Unfortunately, this inner effective torque cannot be measured directly without great measurement effort.

In particular on test benches or in vehicle prototypes on the road, the indicated combustion torque is often measured using indication measurement technology. This is based on the measurement of the cylinder pressure in the cylinders of the internal combustion engine. On the one hand, this is technically complex and costly and is therefore only used on the test bench or in a prototype vehicle on the road. But even if the indication combustion torque is measured, it still does not represent the effective torque of the internal combustion engine, which is obtained by subtracting a frictional torque and other loss torques of the internal combustion engine from the indication combustion torque. The friction torque or a loss torque is generally not known and, of course, is also highly dependent on the operating state (speed, torque, temperature, etc.), but also on the aging state and degree of loading of the internal combustion engine.

A similar problem can also arise with other torque generators, such as an electric motor, where the internal effective torque can possibly not be directly measured. In the case of the electric motor, the internal effective torque would be, for example, the air gap torque, which is not accessible for direct measurement without having to use signals from the power converter.

The problem of the high instrument-based effort for ascertaining the indicated combustion torque has already been solved in that this combustion torque is estimated by an observer from other measurable quantities. In U.S. Pat. No. 5,771,482 A, measurement variables of the crankshaft are used for estimating the combustion torque. Of course, this in turn requires corresponding measurement technology on the crankshaft, but this is usually not available from the outset. In U.S. Pat. No. 6,866,024 B2, measurement variables on the crankshaft are also used to estimate an indicated combustion torque. It uses methods of statistical signal processing (Stochastic Analysis Method and Frequency Analysis Technique). Both approaches do not lead to effective torque.

Other Kalman filter-based observers which estimate the indicated combustion torque have also become known. An example of this is S. Jakubek, et al., “Estimating the internal torque of internal combustion engines using parametric Kalman filtering,” Automation Technology 57 (2009) 8, p. 395-402. Kalman filters are generally computationally complex and can therefore only be used to a limited extent for practical use.

From Jing Na, et al., “Vehicle Engine Torque Estimation via Unknown Input Observer and Adaptive Parameter Estimation,” IEEE Transactions on Vehicular Technology, Volume: PP, Issue: 99, Aug. 14, 2017, an observer for the effective torque of an internal combustion engine is known. This observer is designed as a high-gain observer with the effective torque as an unknown input. The observer is based on filtered (low-pass) measurements of the speed and the torque on the crankshaft of the internal combustion engine and the observer estimates a filtered effective torque, that is to say an average of the effective torque of the internal combustion engine. A high-gain observer is based on the fact that the high gain suppresses non-linear effects caused by the non-linear modeling of the test setup or suppresses it into the background. The non-linear approach makes this concept more difficult. In addition, a lot of information is naturally lost in the measurement signal by filtering the measurements. For example, effects such as torque vibrations due to combustion shocks in an internal combustion engine or vibrations due to switching in a power converter of an electric motor cannot be represented in the estimated effective torque.

Measurement signals are usually noisy, either due to measurement noise and/or system noise, and should therefore often be filtered before further processing, for example in a controller: In addition, measurement signals of certain applications also contain periodic oscillations with a fundamental frequency and harmonic components (harmonics) of certain harmonic frequencies. In many applications, the fundamental frequency, and thus the harmonic frequencies, is not constant, but variable. This makes it difficult to filter such measurement signals.

### SUMMARY

It is therefore an object of the present teaching to provide a filter which is capable of filtering a noisy, periodic measurement signal with oscillations of a variable fundamental frequency and harmonic components of the fundamental frequency.

This object is achieved according to the present teaching in that the measurement signal is low-pass-filtered in a low-pass filter with a cutoff frequency greater than the fundamental frequency, that a harmonic oscillation component of the fundamental frequency is determined in at least one self-adaptive harmonic filter, and the at least one harmonic oscillation component is added to the low-pass-filtered measurement signal, and the resultant sum is substracted from the measurement signal, and the resultant difference is used as input into the low pass filter (LPF), and that measurement signal subjected to low pass filtering in the low-pass filter is output as a filtered measurement signal.

This procedure makes it easy to filter out any noise in the measurement signal. After the sum of the low-pass-filtered measurement signal and a harmonic oscillation component is substracted from the measurement signal, the low-pass filter receives a signal at the input in which the harmonic oscillation component is missing. This oscillation component is of course also missing in the filtered output signal of the filter, which means that both noise and to harmonic waves can be filtered out in a simple manner. Any harmonic oscillation components can of course be filtered out. As the harmonic filter adapts to the variable fundamental frequency, the filter automatically follows a changing fundamental frequency.

The at least one harmonic filter is advantageously implemented as an orthogonal system that uses a d-component and a q-component of the measurement signal, wherein the d-component is in phase with the measurement signal and the q-component is 90° out of phase with the d-component, a first transfer function is established between the input into the harmonic filter and the d-component, and a second transfer function is established between the input into the harmonic filter and the q-component, and gain factors of the transfer functions can be ascertained as a function of the harmonic frequency. If the frequency changes, the gain factors of the transfer functions also change automatically and the harmonic filter tracks the frequency. The d-component is preferably output as a harmonic oscillation component.

In a particularly advantageous embodiment, the low-pass-filtered measurement signal output by the low-pass filter is used in the at least one harmonic filter in order to determine the current fundamental frequency therefrom. This allows the filter to adjust itself automatically to a variable fundamental frequency.

If a plurality of measurement signals are simultaneously filtered using filters according to the present teaching, then it is advantageous if a further measurement signal is filtered with a further filter and the further low-pass-filtered measurement signal output by the low-pass filter of the further filter is used in at least one harmonic filter of another filter in order to determine the current fundamental frequency therefrom. In this way, the two filters can be easily synchronized with each other.

### BRIEF DESCRIPTION OF THE DRAWINGS

The present teaching is described in greater detail in the following with reference to FIGS. 1 to 7, which show exemplary, schematic and non-limiting advantageous embodiments of the present teaching. In the drawings:

FIG. 1 shows an observer structure according to the present teaching for estimating the effective torque,

FIG. 2 shows a test setup with a torque generator and torque sink on a test bench,

FIG. 3 shows a physical model of the test setup,

FIG. 4 shows the structure of a filter according to the present teaching,

FIG. 5 shows the structure of a harmonic filter of the filter according to the present teaching,

FIG. 6 shows a possible combination of the observer and the filter, and

FIG. 7 shows the use of the observer and filter on a test bench.

### DETAILED DESCRIPTION

The present teaching is based on a dynamic technical system having a torque generator DE, for example an internal combustion engine 2 or an electric motor or a combination thereof, and a torque sink DS connected thereto, as shown by way of example in FIG. 2. The torque sink DS is the load for the torque generator DE. On a test bench 1 (for example FIG. 2) for the torque generator DE, the torque sink DS is a load machine 4. In a vehicle with the torque generator DE, the torque sink DS would practically be the resistance which is caused by the entire vehicle. The torque sink DS is of course mechanically coupled to the torque generator DE via a coupling element KE, for example a connecting shaft 3, in order to be able to transmit a torque from the torque generator DE to the torque sink DS, The torque generator DE generates an internal effective torque T_{E}, which serves to accelerate (also negatively) its own inertia J_{E} and the inertia J_{D} of the connected torque sink DS. This internal effective torque TP of the torque generator DE is not, or very difficulty, accessible in terms of measurement technology and according to the present teaching is to be ascertained, i.e. estimated, by an observer UIO.

It is assumed a well known state space representation of the technical dynamic system in the form

\dot{x}=Ax+Bu+Fw

y=Cx.

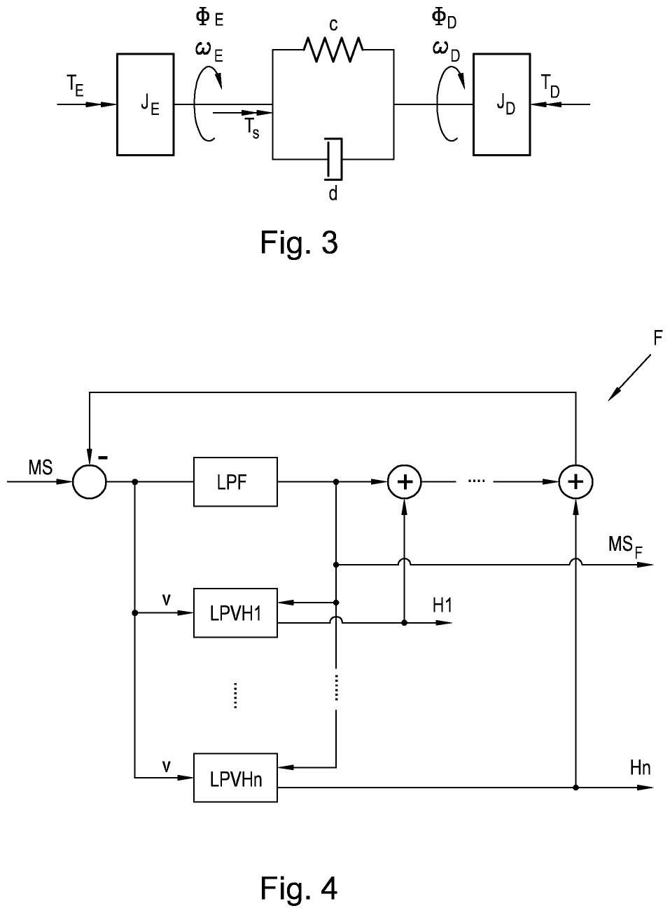

Therein, x denotes the statevector of the technical system, u the known input vector, y the output vector, and w the unknown input. A, B, F, C are the system matrices that result from the modeling of the dynamic system, for example by equations of motion on the model as shown in FIG. 3. Observers with unknown input (UIO) for such dynamic systems are known, for example from Mohamed Darouach, et al., “Full-order observers for linear systems with unknown inputs,” IEEE Transactions on Automatic Control, Institute of Electrical and Electronics Engineers, 1994, 39 (3), pp. 606-609, The observer UIO results by definition in

ż=Nz+Ly+Gu

\hat{x}=z−Ey.

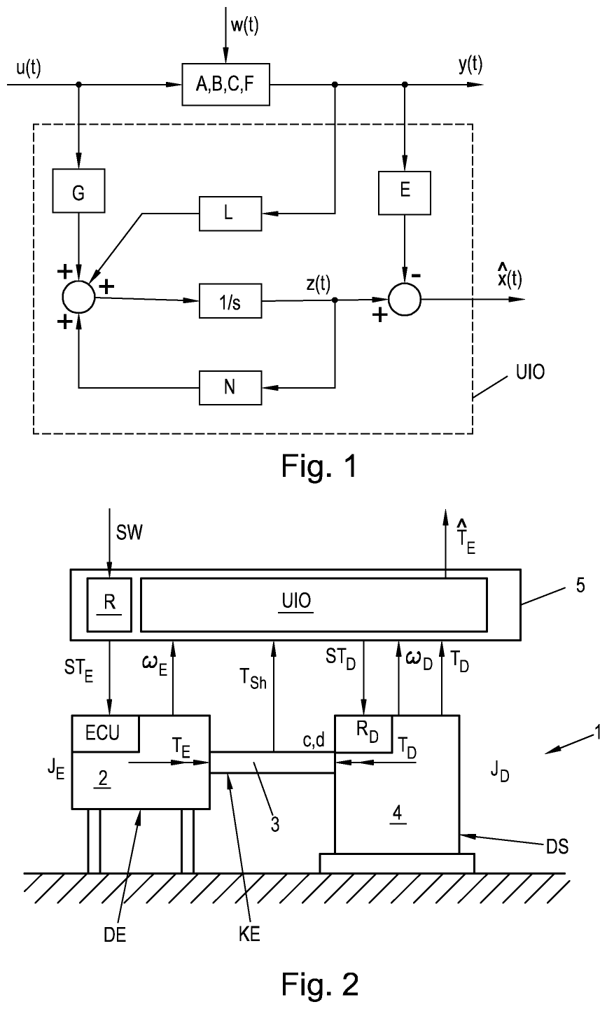

The observer matrices N, L, G, E of the observer structure (FIG. 1) are unknown and must be determined so that the estimated state \hat{x} converges to x. z is an internal state of the observer. The observer UIO thus estimates the state variables x of the dynamic system and allows the calculation of an estimated value for the unknown input w as a function of the observer matrices N, L, G, E and the system matrices A, B, C, F and with the input vector u and the output vector y. The observer error e is introduced with e=\hat{x}−x=z−x−Ey The dynamics of the observer error e then result with the above equations in

ė=Ne+(NM+LC+MA)x+(G−MB)u−MFw

with

M=I+EC and the unit matrix l. In order for the dynamics of the observer error ė to be independent of the unknown input w, ECF=−F must apply and in order for the dynamics of the observer error ė to be independent of the known input u, G=MB must apply. If, in addition, the dynamics of the observer error ė is to be independent of the state x, it also results in N=MA−KC and L=K(l+CE)−MAE. This reduces the dynamics of the observer error ė to ė=Ne The equation ECF=−F can be transformed in the form of E=−F(CF)⁺+Y(I−(CF)(CF)⁺) where the matrix Y represents a design matrix for the observer UIO and ( )⁺ represents the left inverse of the matrix ( ). If a Lyapunov criterion is used for the stability of the dynamics of the observer error ė, the stability criterion N^{T}P+PN<0 results with a symmetrical positive definite matrix P. Whereby the matrix P defines a quadratic Lyapunov function.

With the simplifications U=−F(CF)⁺, V=l−(CF)(CF)⁺ and E=U+YV, the stability criterion can be rewritten in the form

((I+UC)A)^{T}P+P(I+UC)A+(VCA)^{T}Y̅^{T}+Y̅(VCA)−C^{T}K̅^{T}−K̅C<0.

This inequality can be solved for Y̅, K̅, from which Y, K can be calculated as Y=P⁻¹Y̅ and K=P⁻¹K̅. The matrices N, L, G, E can thus be calculated and asymptotic stability can be ensured.

Another stability criterion could, of course, also be used, for example a Nyquist criterion. However, this does not change the basic procedure, only the form of the inequality.

The matrices N, L, G, E are calculated in that a solver available for such problems tries to find matrices N, L, G, E that satisfy the specified inequality. There can be a plurality of valid solutions.

In order to estimate the unknown input w, an interference signal h=Fw can be defined. Thus, this results in E\dot{y}=EC(Ax+Bu)−Fw. The estimated interference signal can then be written in the form ĥ=Ky−E\dot{y}−(KC−ECA)e+ECBu and the estimation error as h−ĥ=−(KC−ECA)e.

The error in the estimate of the disturbance variable h and thus of the unknown input w is consequently proportional to the error e of the state estimate.

An estimate of the unknown input Qv then results in

ŵ=F⁻¹ĥ=F⁻¹(Ky−E\dot{y}−(KC−ECA)e+ECB).

The above observer UIO has the structure as shown in FIG. 1. A major advantage of this observer UIO is that the measurement variables of the input variables u(t) of the input vector u and the output variables y(t) of the output vector y do not have to be filtered, but that the observer UIO can process the unfiltered measurement variables, which can be very noisy for example due to measurement noise or system noise. To make this possible, the observer UIO must be able to separate the noise and the frequency content of a measurement signal of the measurement variable. For this purpose, the observer UIO must be designed so that the dynamics of the observer UIO can follow the expected dynamics of the measurement signal on the one hand and on the other hand does not amplify the expected noise. This is achieved by a suitable choice of the eigenvalues λ of the observer UIO. A rate of change is to be understood as dynamics. If the maximum expected change frequency of the measurement signal is f1, then the lower limit of the eigenvalues f of the observer UIO should be chosen to be a maximum of five times the frequency f1. The expected change frequency of the measurement signal can be determined by the system dynamics, i.e. that the dynamic system itself only allows certain rates of change in the measured measurement signals, or by the measurement signal itself, that is, that the dynamics of the measurement signal is limited by the system, for example by the speed of the measurement technology or by predetermined limits for the speed of the measurement technology. If the noise affects the frequency band greater than the frequency f2, then the upper limit of the eigenvalues f of the observer UIO should be chosen to be at least f2/5. A range f2/5>λ>5·f1 results for the eigenvalues λ of the observer UIO. Since there is usually always high-frequency noise, this separation is usually always possible.

If a plurality of measurement signals is processed in the UIO observer, this is done for all measurement signals and the most dynamic (measurement signal with the greatest rate of change) or the most noisy measurement signal is used.

The eigenvalues λ of the above observer UIO result from the matrix N (from ė=Ne) which determines the dynamics of the observer UIO. The eigenvalues λ are known to be calculated according to λ=det(sl−N)=0, with the unit matrix l and the determinant det.

For the possible solutions for the matrices N, L, G, E, those can be eliminated for which the eigenvalues λ do not satisfy the condition f2/5>λ>5·f1. The remaining solution then defines the observer UIO. If a plurality of solutions remain, one can be selected or other conditions can be taken into account.

Another condition can be obtained from the position of the eigenvalues λ. The eigenvalues λ are usually conjugate complex pairs and can be plotted in a coordinate system with the imaginary axis as ordinate and the real axis as abscissa. It is known from system theory that for reasons of stability the eigenvalues λ should all be placed to the left of the imaginary axis. If a damping angle β is introduced, which denotes the angle between the imaginary axis and a straight line through an eigenvalue λ and the origin of the coordinate system, then this damping angle β for the eigenvalue λ that is closest to the imaginary axis should be in the range π/4 and 3·π/4. The reason for this is that the observer UIO should not, or only slightly, attenuate natural frequencies of the dynamic system.

If the observer UIO is used in combination with a controller R, as will be explained further below, this results in a further condition that the eigenvalues λ of the observer UIO should, related to the imaginary axis, lie to the left of the eigenvalues λ_{R} of the controller R so that the observer UIO is more dynamic (i.e. faster) than the controller R. The real parts of the eigenvalues λ of the observer UIO should therefore all be smaller than the real parts of the eigenvalues λ_{R} of the controller R.

If there is still a plurality of solutions left with the additional conditions, then one of them can be selected, for example a solution with the greatest possible distance between the eigenvalues λ of the observer UIO and the eigenvalues λ_{R} of a controller R or with the greatest possible distance of the eigenvalues λ from the imaginary axis.

A linear system is assumed for the above observer UIO, that is to say with constant parameters of the coupling between the torque generator DE and the torque sink DS, However, the observer described can also be extended to nonlinear systems, as will be explained below.

A nonlinear dynamic system can generally be written in the form

$$\begin{matrix}\dot{x} = Ax + Bu + Mf ( x ) + Fw \\ y = Cx\end{matrix} ,$$

where M denotes the gain of the nonlinearity and is also a system matrix. This applies to Lipschitz nonlinearities for which |f(x₁)−f(x₂)|≤|x₁−x₂ applies. The observer UIO with unknown input w is then given by

$$\begin{matrix}\dot{z} = Nz + Gu + Ly + Mf ( \hat{x} ) \\ \hat{x} = z - Ey\end{matrix}$$

by definition. From this, the observer error e and its dynamics ė can be written again as

$$\begin{matrix}e = \hat{x} - x = z - x - Ey = z - Mx \\ \dot{e} = Ne + ( NM + LC - MA ) x + ( G - MB ) u + M ( f ( \hat{x} ) - f ( x ) ) - MFw\end{matrix} .$$

From the condition that the observer UIO should be independent of the state x, the input u and the unknown input w, the matrices result in MF=0, ECF=−F, N=MA−KC, G=MB, L=K(l+CE)−MAE and M=l+EC. The dynamics ė of the observer error e then results in ė=Ne+(f(x))−f(x)). If a Lyapunov criterion is used again as a stability criterion, this can be written in the form N^{T}P+PN+γPMM^{T}P+γI<0. Therein, γ is a design parameter that can be specified. With the simplifications U=−F(CF)⁺, V=l−(CF)(CF)⁺ and E=U+YV, the stability criterion can be rewritten in the form

((I+UC)A)^{T}P+P(I+UC)A+(VCA)^{T}Y^{T}P+PY(VCA)−C^{T}K^{T}P−PKC++γ(P(I+UC)+PY(VC))(P(I+UC)+PY(VC))^{T}+γI<0.

This inequality can be solved again with an equation solver to obtain Y, K, P. The observer matrices N, L, G, E can thus be calculated and asymptotic stability can be ensured. Using the design parameter γ, the eigenvalues λ can be set via the matrix N as desired and described above.

However, the observer UIO can also be designed in a different way, as will be briefly explained below. For this, for the dynamic system

$$\begin{matrix}\dot{x} = Ax + Bu + Fw \\ y = Cx\end{matrix}$$

an observer structure as above is again assumed:

ż=Zz+TBu+Ky

\hat{x}=z+Hy

e=x−\hat{x}

Therein, z denotes again an internal observer state, \hat{x} the estimated system state, and e an observer error. The matrices Z, T, K, H are again observer matrices with which the observer UIO is designed. The dynamics of the observer error can then be written as

ė=(A−HCA−K₁C)e+(T−(I+HC))Bu+(Z−(A−HCA−K₁C)z+(HC −I)Fw++(K₂−(A−HCA−K₁C)Hy.

For this purpose, for the matrix K=K₁+K₂ was assumed and l again designates the unit matrix. From the condition that the dynamics of the observer error should only depend on the observer error e, it results in

(HC−I)F=0

T=I−HC

Z=A−HCA−K₁C

K₂=ZH.

An estimate of the unknown input ŵ then results in

\hat{w}=(CF)⁺(\dot{y}−CA\hat{x}+CBu) .

The dynamics of the observer error ė=Ze is therefore determined by the matrix Z=(A−HCA−K₁C), and consequently by the matrix K₁, since the other matrices are system matrices or result from them. Therein, the matrix K₁ can be used as a design matrix for the observer UIO and can be used to place the eigenvalues λ of the observer UIO as described above.

The observer UIO with unknown input according to the present teaching generally applies to a dynamic system

$$\begin{matrix}\dot{x} = Ax + Bu + Fw \\ y = Cx\end{matrix} or \begin{matrix}\dot{x} = Ax + Bu + Mf ( x ) + Fw \\ y = Cx\end{matrix} .$$

This is explained on the basis of a test bench 1 for an internal combustion engine 2 (torque generator DE). which is connected to a load machine 4 (torque sink DS) with a connecting shaft 3 (coupling element KE) (as shown in FIG. 2).

On the test bench 1, the internal combustion engine 2 and the load machine 4 are controlled by a test bench control unit 5 for carrying out a test run. The test run is usually a sequence of setpoints SW for the internal combustion engine 2 and the load machine 4, which are set by suitable controllers R in the test bench control unit 5. Typically, the load machine 4 is controlled to a dyno speed ω_{D} and the internal combustion engine 2 to a shaft torque T_{S}. A gas pedal position α, which is converted by an engine control unit ECU into quantities such as injection quantity, injection timing, setting of an exhaust gas recirculation system, etc., serves as the manipulated variable ST_{E} for internal combustion engine 2, which is calculated by controller R from setpoints SW and measured actual values. A setpoint torque T_{Dsoll}, which is converted by a dyno controller R_{D} into corresponding electrical currents and/or voltages for the load machine 4, serves as the manipulated variable ST_{D} for the load machine 4. The setpoint values SW for the test run are determined, for example, from a simulation of a vehicle driving with the internal combustion engine 2 along a virtual route, or are simply available as a chronological sequence of setpoint values SW. For this purpose, the simulation is to process the effective torque T_{E} of the internal combustion engine 2, which is estimated with an observer UIO as described above. The simulation can take place in the test bench control unit 5, or in a separate simulation environment (hardware and/or software).

The dynamic system of FIG. 2 thus consists of the inertia J_{E} of the internal combustion engine 2 and the inertia J_{D} of the load machine 4, which are connected by a test bench shaft 4, which is characterized by a torsional rigidity c and a torsional damping d, as shown in FIG. 3. These dynamic system parameters, which determine the dynamic response of the dynamic system, are assumed to be known.

On the test bench 1, actual values of the speed ω_{E} of the internal combustion engine 2, the shaft torque T_{S}, the speed ω_{D} of the load machine 4 and the torque T_{D} of the load machine 4 are usually measured using suitable, known measuring sensors such as rotary encoders and torque sensors. However, not all measurement variables are always available, since not all la measurement variables are always measured on every test bench 1. With an appropriate configuration, the observer UIO can cope with that, however, and can in any case estimate the effective torque \hat{T}_{E} of the internal combustion engine 2. This is explained according to FIG. 3 using the dynamic model of the combination of internal combustion engine 2, test bench shaft 3, and load machine 4.

In a first possible variant, only the internal combustion engine 2 is considered and it results in the equation of motion J_{E}\dot{ω}_{E}=T_{E}−T_{S} with y=ω_{E}. If T_{E} is used as unknown input w, the shaft torque T_{S} follows as input variable u, ω_{E} as state variable x, and the system matrices result in A=1/J_{E}, B=−1, C=1, F=1. The observer UIO can thus be configured, which then determines an estimated value for the effective torque \hat{T}_{E} of the internal combustion engine 2 from measurement signals of the shaft torque T_{S}.

In a second variant, the model of the dynamic system also includes the connecting shaft 3 and the torque T_{D} of the load machine 4 is used as the input u. The speed Wω_{E} of the internal combustion engine 2 and the shaft torque T_{S} are used as the output. The input u and the outputs y are measured on the test bench 1 for the implementation of the observer UIO as measurement signals. The state vector x is defined with x^{T}=[ΔΦω_{D}ω_{E}], where Δφ is the difference between the twist angle φ_{E} of the connecting shaft 3 on the internal combustion engine 2 and the twist angle φ_{D} of the connecting shaft 3 on the load machine 4, i.e. Δφ=φ_{E}−φ_{D}. The unknown input w is the effective torque T_{E} of the internal combustion engine 2. From this, with the equations of motion, that are written for the dynamic system of

FIG. 3 for this case, the system matrices A, B, C, F follow as

$$A = [ \begin{matrix}0 & - 1 & 1 \\ \frac{c}{{J}_{D}} & - \frac{d}{{J}_{D}} & \frac{d}{{J}_{D}} \\ - \frac{c}{{J}_{E}} & - \frac{d}{{J}_{E}} & \frac{d}{{J}_{E}}\end{matrix} ] , B = [ \begin{matrix}0 \\ - \frac{1}{{J}_{D}} \\ 0\end{matrix} ] , C = [ \begin{matrix}0 & 0 & 1 \\ c & - d & d\end{matrix} ] , and F = [ \begin{matrix}0 \\ 0 \\ \frac{1}{{J}_{E}}\end{matrix} ] .$$

The observer UIO can thus be configured, which then determines an estimated value for the effective torque \hat{T}_{E} of the internal combustion engine 2 from the measurement variables.

In a third variant, the model again comprises the entire dynamic system with internal combustion engine 2, connecting shaft 3, and load machine 4. No input u is used. The speed ω_{E} of the internal combustion engine 2, the speed ω_{D} of the load machine 4, and the shaft torque T_{S} are used as the output y. The outputs y are measured on the test bench 1 for the implementation of the observer UIO as measurement signals. The state vector x is again defined with x^{T}=[Δφω_{D}ω_{E}]. The unknown input w is the effective torque T_{E} of the internal combustion engine 2. From this, with the equations of motion, that are written for the dynamic system of FIG. 3 for this case, the system matrices A, B, C, F follow as

$$A = [ \begin{matrix}0 & - 1 & 1 \\ \frac{c}{{J}_{D}} & - \frac{d}{{J}_{D}} & \frac{d}{{J}_{D}} \\ - \frac{c}{{J}_{E}} & - \frac{d}{{J}_{E}} & \frac{d}{{J}_{E}}\end{matrix} ] , B = 0 , C = [ \begin{matrix}0 & 1 & 0 \\ 0 & 0 & 1 \\ c & - d & d\end{matrix} ] , and F = [ \begin{matrix}0 \\ 0 \\ \frac{1}{{J}_{E}}\end{matrix} ] .$$

The observer UIO can thus be configured, which then determines an estimated value for the effective torque \hat{T}_{E} of the internal combustion engine 2 from the measurement variables.

In a fourth variant, the model again comprises the entire dynamic system with internal combustion engine 2, connecting shaft 3, and load machine 4. As input u the torque T_{D} of the load machine 4 is used. The speed ω_{E} of the internal combustion engine 2 and the speed ω_{D} of the load machine 4 are used as the output y. The inputs u and the outputs y are measured on the test bench 1 for the implementation of the observer UIO as measurement signals. This version is particularly advantageous because no measured value of the shaft torque T_{S} is required to implement the observer UIO, which means that a shaft torque sensor can be saved on the test bench. The state vector x is again defined with x^{T}=[Δφω_{D}ω_{E}]. The unknown input w is the effective torque T_{E}, of the internal combustion engine 2. From this, with the equations of motion, that are written for the dynamic system of FIG. 3 for this case, the system matrices A, B, C, F follow as

$$A = [ \begin{matrix}0 & - 1 & 1 \\ \frac{c}{{J}_{D}} & - \frac{d}{{J}_{D}} & \frac{d}{{J}_{D}} \\ - \frac{c}{{J}_{E}} & - \frac{d}{{J}_{E}} & \frac{d}{{J}_{E}}\end{matrix} ] , B = [ \begin{matrix}0 \\ - \frac{1}{{J}_{D}} \\ 0\end{matrix} ] , C = [ \begin{matrix}0 & 0 & 1 \\ 0 & 1 & 0\end{matrix} ] , and F = [ \begin{matrix}0 \\ 0 \\ \frac{1}{{J}_{E}}\end{matrix} ] .$$

The observer UIO can thus be configured, which then determines an estimated value for the effective torque \hat{T}_{E}, of the internal combustion engine 2 from the measurement variables.

As mentioned above, the state variables of the state vector x are simultaneously estimated by the observer UIO.

Depending on the existing test bench structure, in particular depending on the existing measurement technology, a suitable observer UIO can accordingly be configured, which makes the observer UIO according to the present teaching very flexible. Of course, more complex test bench setups, for example with more oscillatable masses, for example with an additional dual mass flywheel, or other or additional couplings between the individual masses, can also be modeled in the same way using the dynamic equations of motion. From the resulting system matrices A, B, C, F, the observer UIO can then be configured in the same way for the effective torque T_{E}.

The observer UIO can of course also be used in a different application than on the test bench 1. In particular, it can also be used in a vehicle having an internal combustion engine 2 and/or an electric motor as a torque generator DE. The observer UIO can be used to estimate the effective torque \hat{T}_{E} of the torque generator DE from available measurement variables, which can then be used to control the vehicle, for example in an engine control unit ECU, a hybrid drive train control unit, a transmission control unit, etc. Since the observer UIO according to the present teaching works with unfiltered, noisy measurement signals, the estimated value for the effective torque \hat{T}_{E} will also be noisy. Likewise, the estimated value for the effective torque \hat{T}_{E} will also contain harmonic components, which result from the fact that the effective torque T_{E} results from the combustion in the internal combustion engine 2 and the combustion shocks generate a periodic effective torque T_{E} with a fundamental frequency and harmonics. This can be desirable for certain applications. In particular, the vibrations introduced by the combustion shocks are often to be reproduced on the test bench, for example if a hybrid drive train is to be tested and the effect of the combustion shocks on the drive train is to be taken into account. However, there may also be applications in which a noisy effective torque \hat{T}_{E} superimposed with harmonics is undesirable, for example in a vehicle. The fundamental frequency w of the combustion shocks, and of course the frequencies of the harmonics, of course, depends on the internal combustion engine 2, in particular the number of cylinders and type of the internal combustion engine 2 (e.g. gasoline or diesel, 2-stroke or 4-stroke, etc.), but also from the current speed WE of the internal combustion engine 2. Due to the lo dependence on the speed ω_{E} of the internal combustion engine 2, a filter F for filtering a periodic, noisy, harmonic distorted measurement signal MS is not trivial.

However, the effective torque \hat{T}_{E} of an electric motor generally also includes periodic vibration with harmonics, which in this case can result from switching in a power converter of the electric motor. These vibrations are also speed-dependent. The filter F according to the present teaching can also be used for this.

The present teaching therefore may also include a filter F which is suitable for measurement signals MS, which is periodic in accordance with a variable fundamental frequency ω and is distorted by harmonics of the fundamental frequency ω and can also be noisy (due to measurement noise and/or system noise). The filter F can be applied to any such measurement signals MS, for example measurements of a speed or a torque, a rotation angle, an acceleration, a speed, but also an electrical current or an electrical voltage. The filter F is also independent of the observer UIO according to the present teaching, but can also process an effective torque \hat{T}_{E} estimated by the observer as the measurement signal MS. The filter F represents therefore an independent present teaching.

The filter F according to the present teaching comprises a low-pass filter LPF and at least one self-adaptive harmonic filter LPVHn for at least one harmonic frequency ωₙ, as n times the fundamental frequency ω, as shown in FIG. 4. Normally, a plurality of harmonic filters LPVHn is provided for different harmonic frequencies ωₙ, whereby the lower harmonics are preferably taken into account. Of course, n does not have to be an integer, but only depends on the respective measurement signal MS or its origin. However, n can generally be assumed to be known from the respective application. Since the fundamental frequency ω is variable, the harmonic frequencies ωₙ are of course also variable, so that the harmonic filters LPVHn are self-adaptive with regard to the fundamental frequency ω, that is to say that the harmonic filters LPVHn automatically adjust to a change in the fundamental frequency ω.

The low-pass filter LPF is used to filter out high-frequency noise components of the measurement signal MS and can be set to a specific cutoff frequency ω_{G}, which can of course be dependent on the characteristic of the noise. The low-pass filter LPF can be implemented, for example, as an IIR filter (filter with an infinite impulse response) with the general form in z-domain notation (since the filter F will generally be implemented digitally).

y(k)=b₀x(k)+ . . . +b_{N-1}x(k−N+1)−a₁y(k−1)− . . . −a_{M}y(k−M)

Therein, y is the filtered output signal and x is the input signal (here the measurement signal MS), in each case at the current point in time k and at past points in time. The filter can be designed using known filter design methods in order to obtain the desired filter response (in particular cutoff frequency, gain, phase shift). A simple low-pass filter of the form

$$LPF ( Z ) = \frac{{k}_{0}}{Z - 1 + {k}_{0}}$$

can be derived from this. Therein, k₀ is the only design parameter that can be adjusted with regard to the desired dynamics and noise suppression. The rule here is that a fast low-pass filter LPF will generally have poorer noise suppression, and vice versa. Therefore, a certain compromise is usually set in between with the parameter k₀.

However, any other implementation of a low-pass filter LPF is of course also possible, for example as an FIR filter (filter with finite impulse response).

The output of the low-pass filter LPF is the filtered measurement signal MS_{F}, from which the noise components have been filtered. The low-pass filter LPF generates a moving average. The input of the low-pass filter LPF is the difference between the measurement signal MS and the sum of the mean value of the measurement signal MS and the harmonic components Hn taken into account. The low-pass filter LPF thus only processes the alternating components of the measurement signal MS at the fundamental frequency ω (and any harmonics that remain).

The harmonic filter LPVHn ascertain the harmonic components Hn of the measurement signal MS. The harmonic components are vibrations with the respective harmonic frequency. The harmonic filter LPVHn is based on an orthogonal system that is implemented on the basis of a generalized integrator of the second order (SOGI). An orthogonal system generates a sine vibration (d component) and an orthogonal cosine vibration (90° phase shift; q component) of a certain frequency ω—this can be seen as a rotating pointer in a dq-coordinate system that rotates with ω and which thus maps the harmonic vibration. The SOGI is defined as

$$G ( s ) = k \frac{s ω}{{s}^{2} + {ω}^{2}}$$

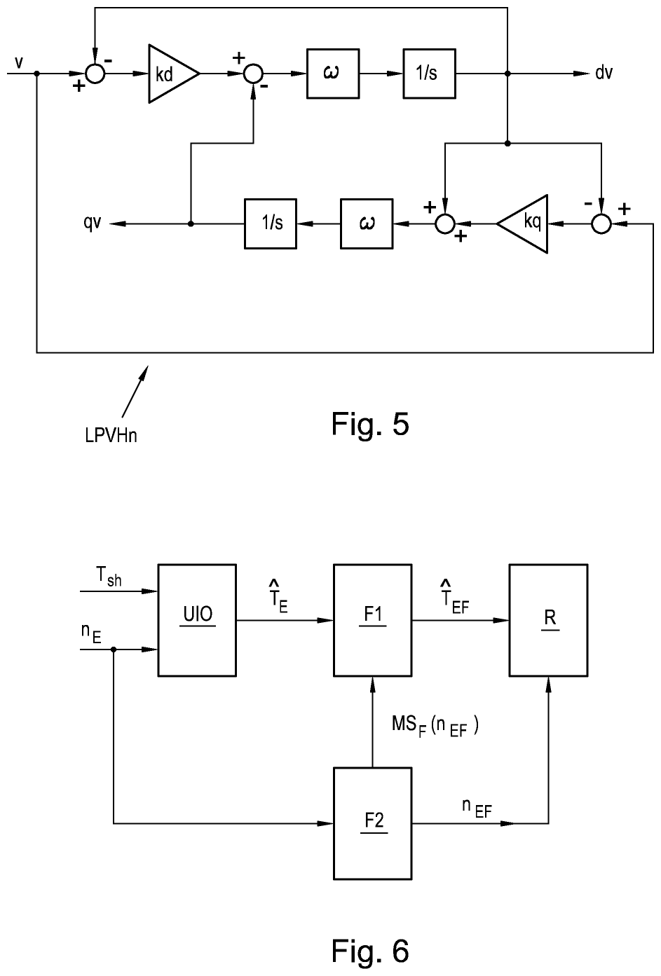

and has a resonance frequency at ω. The orthogonal system in the harmonic filter LPVHn has the structure as shown in FIG. 5. dv has the same phase as the fundamental vibration of the input v and preferably also the same amplitude. qv is 90° out of phase. The transfer function G_{d}(s) between dv and v and the transfer function G_{q}(s) between qv and v thus result in

$${G}_{d} ( s ) = \frac{{k}_{d} s - ω {k}_{q}}{{s}^{2} + {k}_{d} s + {ω}^{2} - ω {k}_{q}} and {G}_{d} ( s ) = \frac{{k}_{q} s + ω {k}_{d}}{{s}^{2} + {k}_{d} s + {ω}^{2} - ω {k}_{q}} .$$

The harmonic component Hn of the harmonic filter LPVHn corresponds to the d component.

Due to the integrating response of the harmonic filter LPVHn, if there is a change at the input of the harmonic filter LPVHn, the output will settle to the new resonance frequency, with which the harmonic component Hn will track a change in the measurement signal MS. If the measurement signal MS does not change, the harmonic component Hn does not change after settling.

The goal is now to set the gains k_{d}, k_{q} as a function of the frequency ω so that the harmonic filter LPVHn can adapt itself to variable frequencies. For this, for example, a Luenberger observer approach (A−LC) can be chosen with the pole placement of the eigenvalues.

$$A = [ \begin{matrix}0 & - ω \\ ω & 0\end{matrix} ]$$

is the system matrix and C=[1 0] the output matrix, whereby only the d components are taken into account in the output. Thus, this results in

$$( A - LC ) = [ \begin{matrix}0 & - ω \\ ω & 0\end{matrix} ] - [ \begin{matrix}{k}_{d} \\ {k}_{q}\end{matrix} ] = [ \begin{matrix}- {k}_{d} & - ω \\ ω - {k}_{q} & 0\end{matrix} ] .$$

The eigenvalues λ thus result in

$$( λ I - ( A - LC ) ) = 0 = \vert \begin{matrix}λ + {k}_{d} & ω \\ - ω + {k}_{q} & λ\end{matrix} \vert .$$

By solving the equation, it finally results in the eigenvalues

$$λ = \frac{{k}_{d}}{2} \pm \frac{1}{2} \sqrt{{k}_{d}^{2} - 4 ( - {k}_{q} ω + {ω}^{2} )} .$$

As it is the goal that the modes of vibration of the eigenvalues λ have the same frequency as the frequency of the harmonics in the harmonic filter LPVHn, it follows ½{square root over (k_{d}²−4(−k_{q}ω+ω²)}−jω, which leads to k_{d}²+4k_{q}ω=0. By introducing a design parameter α=k_{d}²+k_{q}², ultimately k_{q}=2ω±\sqrt{4ω²+α} is obtained with k_{d}²=−4k_{q}ω. This leads to the equations for the two gains k_{d} and k_{q} in the form k_{d}=\sqrt{α−k_{q}²} and k_{q}=2ω−\sqrt{4ω²+α}. From this, it can be seen that the gains k_{d} and k_{q} can simply be adapted to a changing frequency ω and thus can be tracked to the frequency ω. The harmonic filter LPVHn for the nth harmonic vibration at the fundamental frequency ω can then be achieved by simply using the n-fold frequencies n·ω in the equations for the gains k_{q}: k_{q}=2ω−\sqrt{4nω²+α}.

The design parameter a can be chosen appropriately. For example, the design parameter α can be selected from the signal-to-noise ratio in the input signal v of the harmonic filter LPVHn. If the input signal v contains little to no noise, the design parameter α>1 can be selected. However, if the input signal v is noisy, the design parameter α<1 should be selected.

The current fundamental frequency ω, which is required in the harmonic filter LPVHn, can in turn be obtained from the mean value generated by the low-pass filter LPF, since it also contains the fundamental frequency ω. Therefore, the output from the low-pass filter LPF is provided in FIG. 4 as a further input into the harmonic filter LPVHn. The current fundamental frequency ω can of course also be provided in another way. For example, this could also be calculated from the knowledge of an internal combustion engine 2 and a known current speed of the internal combustion engine 2.

A preferred use of the filter F is shown in FIG. 6. The observer UIO according to the present teaching estimates, for example, from the measured shaft torque T_{Sh} and the speed n_{E} of an internal combustion engine 2 (for example on a test bench 1 or in a vehicle) the internal effective torque \hat{T}_{E} of the internal combustion engine 2 (torque generator DE). The periodic, noisy, estimated effective torque \hat{T}_{E} superimposed with the harmonics Hn is filtered in a downstream filter F1. The resulting mean value \hat{T}_{EF} can be further processed, for example, in a controller R or in a control unit of a vehicle.

In most cases, the observer UIO processes at least two input signals u(t), as in FIG. 6, the shaft torque T_{Sh} and the speed n_{E}. In a particularly advantageous embodiment, one of the two signals can thus be used to synchronize another signal, which is advantageous for further processing. For example, an input signal into the observer UIO can be filtered with a filter F2 according to the present teaching. The mean value MS_{F} generated thereby (here n_{EF}) can then be processed in a second harmonic filter F1 for the estimated effective torque \hat{T}_{E} in order to obtain the information about the current fundamental frequency ω therefrom and thus to synchronize the two filters F1, F2 at the same time with one another. The two filtered output signals of the two filters F1, F2 are thus synchronized with one another.

However, a filter F according to the present teaching can also be used entirely without an observer UIO, for example to filter a periodic, noisy, and harmonic-superimposed signal in order to process the filtered signal further. In a specific application of the torque generator DE, for example on a test bench 1, a measured measurement signal MS, for example a shaft torque T_{Sh} or a speed n_{E}, n_{D}, can be filtered by a filter F according to the present teaching. This allows either the unfiltered signal or the filtered signal to be processed as required.

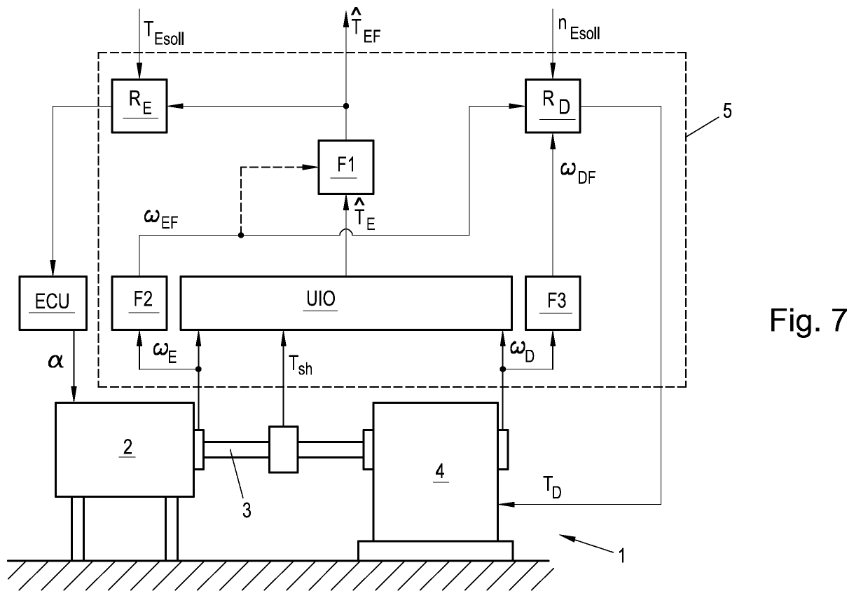

A typical application of the observer UIO and filter F according to the present teaching is shown in FIG. 7. A test arrangement with an internal combustion engine 2 as a torque generator DE and a load machine 4 as a torque sink DS, which are connected by a connecting shaft 3, is arranged on the test bench 1. To carry out a test run, a setpoint torque T_{Esoll} of the internal combustion engine 2 and a setpoint speed n_{Esoll} of the internal combustion engine 2 are specified. The setpoint speed n_{Esoll} is adjusted in this case with a dyno controller R_{D} with the load machine 4 and the setpoint torque T_{Esoll} with a motor controller R_{E} directly on the internal combustion engine 2. The effective torque \hat{T}_{E} of the internal combustion engine 2 is estimated with an observer UIO as the actual value for the engine controller R_{E} from the measurement variables of the shaft torque T_{Sh}, the speed ω_{E} of the internal combustion engine 2 and the speed ω_{D} the load machine. The estimated effective torque \hat{T}_{E} is filtered in a first filter F1 and transferred to the engine controller R_{E}, which controls the internal combustion engine 2, for example via the engine control unit ECU. The dyno controller R_{D} obtains the current measured engine speed ωₑ and the measured speed of the load machine ω_{D} as the actual values and calculates a torque T_{D} of the load machine 4, which is to be set on the load machine 4. However, the dyno controller R_{D} does not process the measured measurement signals, but rather the filtered measurement signals ω_{EF}, ω_{DF}, which are filtered in a second and third filter F2, F3 according to the present teaching. As described with reference to FIG. 6, the first filter F1 can also be synchronized to the speed ω_{E} of the internal combustion engine 2, as indicated by the dashed line.

A filter F according to the present teaching can be switched on or off as required or depending on the application. For example, a controller R that processes the estimated effective torque \hat{T}_{E} can work with either the unfiltered or the filtered estimated values for the effective torque.

1. A method for filtering a periodic, noisy measurement signal with a fundamental frequency and harmonic oscillation components of the fundamental frequency with a filter comprising:
subjecting the measurement signal to low pass filtering in a low-pass filter of the filter with a cutoff frequency greater than the fundamental frequency,
determining a harmonic oscillation component of the measurement signal as an n-fold of the fundamental frequency in at least one self-adaptive harmonic filter of the filter,
adding the at least one harmonic oscillation component to the low-pass-filtered measurement signal, subtracting the resultant sum from the measurement signal, and using the resultant difference as input into the low pass filter, and
outputting the measurement signal subjected to low pass filtering in the low-pass filter by the filter as filtered measurement signal.

2. The method according to claim 0, wherein the at least one self-adaptive harmonic filter is implemented as an orthogonal system that uses a d-component and a q-component of the measurement signal, wherein the d-component is in phase with the measurement signal and the q-component is 90° out of phase with the d-component, and
a first transfer function is established between the input into the harmonic filter and the d-component, and a second transfer function is established between the input into the harmonic filter and the q-component, and gain factors of the transfer functions are determined as a function of the harmonic frequency.

3. The method according to claim 0, wherein the d-component is used as a harmonic oscillation component.

4. The method according to claim 0, wherein the low-pass filtered measurement signal output by the low-pass filter is used in the at least one harmonic filter to determine the current fundamental frequency.

5. The method according to claim 0, wherein a further measurement signal is filtered with a further filter and a low-pass-filtered additional measuring signal output by a low-pass filter of the further filter is used in the at least one harmonic filter of the filter to determine the current fundamental frequency.

6. A method of using the filter according to claim 1 on a test bench for a test object with a torque generator which is connected to a torque sink via a coupling element, comprising:
controlling the torque generator or the torque sink with a controller for performing a test run,
wherein the controller processes at least one measurement signal from the test bench, and
the at least one measurement signal is filtered upstream of the controller in the filter.

7. A method of using the filter according to claim 1 on a test bench for a test object with a torque generator which is connected to a torque sink via a coupling element, comprising:
controlling the torque generator or the torque sink with a controller for performing a test run,
wherein the controller processes an effective torque of the torque generator,
an estimated value for the effective torque \hat{T}_{E} is calculated in an observer for the effective torque of the torque generator, and
the estimated effective torque \hat{T}_{E} is filtered in the filter before being used in the controller.
